(19) United States
(12) Patent Application Publication
(10) Pub. No.: US 2024/0090148 A1
(43) Pub. Date: Mar. 14, 2024

(54) 19-INCH WALL-MOUNTED CABINET FOR COMPUTER AND INDOOR COMMUNICATIONS NETWORK DEVICES WITH SIDE COVERS

(71) Applicant: Apichart SAJCHWONG, Samut Prakan (TH)

(72) Inventor: Apichart SAJCHWONG, Samut Prakan (TH)

(73) Assignee: Cheval Electronic Enclosure Company Limited, Samut Prakan (TH)

(21) Appl. No.: 17/626,871

(22) PCT Filed: Sep. 9, 2021
(86) PCT No.: PCT/TH2021/000052

§ 371 Date: Dec. 8, 2022

(30) Foreign Application Priority Data
Jun. 1, 2021 (TH) 2101003143

(51) Int. Cl. H05K 5/03; H05K 5/02

(52) U.S. Cl. CPC H05K 5/03; H05K 5/0221

(57) ABSTRACT

The 19-inch Wall-mounted Cabinet for Computer and Indoor Communications Network Devices with Side Covers has a design that depends on the side frame model to reinforce the structure. The aforementioned frame was designed to have a rectangular frame (12) made from metal into pipes assembled to the upper frame (13) and the lower frame (14) used for installing the top cover (1) and the bottom cover (2). The mechanism for assembling the top cover (1) and the bottom cover (2) to the right frame (7) and the left frame (8) with wedges uses force to make the designed wedges lock into the aforementioned positions in order to assemble the structure together without need for screws. The side cover opening mechanism which does not need to be removed consists of the side lock bracket (19) assembled to side covers (18). The interior has a pin lock position joined to the second side (20) which has a spring lock (22) and a range pin lock position (21) assembled together as a mechanism allowing side covers to hook and lock to the invention. The upper corner in the opposite direction consists of mechanisms functioning as rotation points for side covers (18), which consist of the collet (26) that has a pin mechanism (23) with a spring (24) and a position pin lock (25) working together as points of rotation when side covers (18) are closed or opened. The locking mechanism is such that the first wall bracket (17) and the side lock bracket (19) lock the pin lock position of the second side bracket (20) and the side lock bracket (19) to prevent movement when opening-closing the door. This new design of the 19-inch Wall-mounted Cabinet for Computer and Indoor Communications Network Devices with Side Covers solves problems in assembling the invention to increase speed of assembly and enable more appropriate use of ordinary one-piece 19-inch wall mounted cabinet inventions while having durability and more convenient use in opening side covers without need to remove side covers.

### BRANCH OF SCIENCE ASSOCIATED WITH THE INVENTION

Engineering in parts concerned with the 19-inch Wall-mounted Cabinet for Computer and Indoor Communications Network Devices with a Side Cover.

### BACKGROUND OF RELATED ART OR SCIENCE

In using computer networks, computer connection devices must be connected to a network covering the entire area of use. The aforementioned devices must be installed in 19-inch wall-mounted cabinets that usually contain network equipment with characteristics of cable hubs or safety devices for network systems that fit IEC 297 standards with a 19″ front width. In general, devices are installed inside one-piece and two-piece 19-inch wall-mounted cabinets with characteristics of a wall-mounted rectangular box with a rear cover that is a rectangular box for attachment to the front structure with hinges installed at any side of the two-piece 19-inch wall-mounted cabinet, a design allowing front and rear parts to be open separately. Inventions popularly used for installing network devices or signal repeater devices popularly use one piece 19-inch cabinet for computer and indoor communication network devices, which vary in height, use and capacity to support signal repeater devices. During installation, 19-inch cabinets are directly mounted on walls and installation devices are used by opening the front cover and the side cover to reach devices within. Side covers are required for installation, maintenance or inspection of devices inside the cabinet when side covers need to be removed and placed on the 19-inch wall-mounted cabinet or other places. In most cases, the aforementioned cabinet is installed aboveground, which may make opening and removing side covers inconvenient. In this new design, the invention aims to have a design that is convenient to use with structural durability.

### DESCRIPTION AND PURPOSE OF THE INVENTION

The structure of the 19-inch wall-mounted cabinet for computer and indoor communication Networking devices is designed with metal pipes used as the main structure to provide the invention with durability capable of supporting weight of devices and strong wall mounts to facilitate assembly of various parts. Thus, the invention was designed to be assembled without screws and rivets while retaining shape and durability.

The 19-inch Wall-mounted Cabinet for Computer and Indoor Communication Network Devices with Side Covers in this invention was designed to solve problems from difficulty in storing side covers when having no place for storage after opening while making assembly fast and suitable for current uses.

### FULL DISCLOSURE OF INVENTION

The 19-inch Wall-mounted Cabinet for Computer and Indoor Communications Network Devices with Side Covers has invention details shown in diagrams as follows:

FIG. 1 shows an overall view of the wall-mounted cabinet for computer and indoor communications network devices with side covers.

FIG. 2 shows an image of a wall-mounted cabinet for computer and indoor communications network devices with side covers capable of opening on the left and right sides without need to remove side covers

FIG. 3 shows an image of main structural components of the wall-mounted cabinet for computer and indoor communications network devices with side covers consisting of the top cover (1), the bottom cover (2), the left frame (3), the right frame (4), the rear cover (5) and the front door (6) assembled to the structure of the aforementioned wall-mounted cabinet held to the right frame (7) and the left frame (8). The structure is durable and consists of the right post (9) and the left post (10) functioning as pieces for assembling devices to the wall-mounted cabinet for computer and indoor communications network devices with side covers.

FIG. 4 (see FIG. 3) shows an image of the left frame with the spring valve (11) attached to the invention in order to allow complete function of the cabinet's grounding system.

FIG. 5 shows a set assembled to the left frame (8) which has the same characteristics as the right frame (7) with a rectangular frame (12) made from metal into pipes assembled to the upper frame (13) and the lower frame (14) used for installing the top cover (1) and the bottom cover (2) while functioning as a position to mark assembly range for the right post (9) and the left post (10), which function as pieces for assembling devices to be attached to the wall-mounted cabinet for computer and indoor communications network devices with side covers. The front of the left frame (8) has a front collet assembled to side cover locking mechanisms.

FIG. 6 shows an image of the left side frame (7) mechanism

which has the same characteristics as the right-side frame (8) mechanism consisting of the side cover (18) with mechanisms consisting of the mechanism for locking the side cover to side frames, which will have side lock bracket (19) assembled to side covers (18). The interior has a pin lock position joined to the second side (20) which has a spring lock (22) and a range pin lock position (21) assembled together as a mechanism allowing side covers to hook and lock to the invention. The upper corner in the opposite direction consists of mechanisms functioning as rotation points for side covers (18), which consist of the collet (26) that has a pin mechanism (23) with a spring (24) and a position pin lock position (25) working together as points of rotation when side covers (18) are closed or opened. The locking mechanism functions together.

In FIG. 7, the first wall bracket (17) and the side locking bracket (19) lock the position of the second side bracket pin lock position (20) and the side locking bracket (19) together to prevent movement when opening-closing.

FIG. 8 shows the mechanism for structural assembly of the left frame (3), the right frame (4) and the bottom cover (2). The mechanism is designed to have the same characteristics as assembly of the top cover (1), depending on a design in which wedges at the edge of the bottom cover (2) and the top cover (1) to be inserted into positions at the edge of the lower assembly frame (14) for the bottom cover (2) and the upper assembly frame (13) for the top cover (1) in FIG. 8-1 and FIG. 8-2. Force is used to make the designed wedges lock into the aforementioned positions by beginning from assembling the bottom cover (2) before assembling the wedge in the position of the top cover (1), which will create the structure of the 19-inch Wall-mounted Cabinet for Computer and Indoor Communications Network Devices with Side Covers. Next, the rear cover (5), the left frame(3), the right frame (4) and the front door (6) are assembled in that order.

### BRIEF DESCRIPTION OF DRAWINGS

FIG. 1 shows the 19-inch Wall-mounted Cabinet for Computer and Indoor Communications Network Devices with Side Covers.

FIG. 2 shows the 19-inch Wall-mounted Cabinet for Computer and Indoor Communications Network Devices with Side Covers when side covers are opened.

FIG. 3 shows details of parts assembled to the 19-inch Wall-mounted Cabinet for Computer and Indoor Communications Network Devices with Side Covers.

FIG. 4 shows the frame piece of the 19-inch Wall-mounted Cabinet for Computer and Indoor Communications Network Devices with Side Covers.

FIG. 5 shows details of parts assembled to the left side frame.

FIG. 6 shows details of parts assembled to side covers.

FIG. 7 shows an image demonstrating functions of opening-closing side covers.

FIG. 8 shows details of structural assembly between the left frame (8), the right frame (9) and the bottom cover (2).

### BEST INVENTION METHOD

As stated in the Full Disclosure of Invention.

1. Side cover opening mechanisms without need for removal of the 19-inch Wall-mounted Cabinet for Computer and Indoor Communications Network Devices with Side Covers.

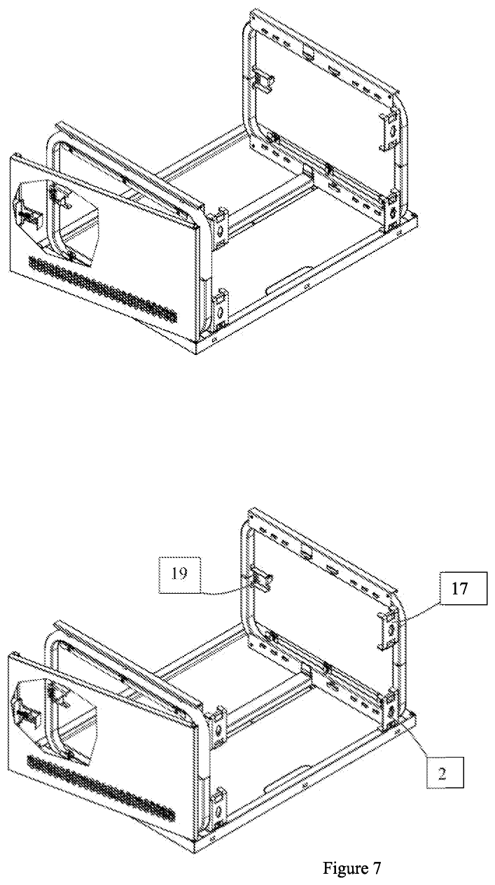

2. The side cover opening mechanism, which does not need to be removed, consists of the side lock bracket (19) assembled to side covers (18). The interior has a pin lock position joined to the second side (20) which has a spring lock (22) and a range pin lock position (21) assembled together as a mechanism allowing side covers to hook and lock to the invention. The upper corner in the opposite direction consists of mechanisms functioning as rotation points for side covers (18), which consist of the collet (26) that has a pin mechanism (23) with a spring (24) and a position pin lock position (25) working together as points of rotation when side covers (18) are closed or opened. This is consistent with FIG. 6 in which the locking mechanism functions together as shown in FIG. 7 with the first wall bracket (17) and the side lock bracket (19) locking the pin lock position of the second side bracket (20) and the side lock bracket (19) to prevent movement when opening-closing the door.

3. The side frames of the 19-inch Wall-mounted Cabinet for Computer and Indoor Communications Network Devices were a design consisting of the rectangular frame (12) made from metal into pipes assembled to the upper frame (13) and the lower frame (14) used for installing the top cover (1) and the bottom cover (2) while functioning as a position to mark assembly range for the right post (9) and the left post (10), which function as pieces for assembling devices that will be assembled to the wall-mounted cabinet for computer and indoor communications network devices with side covers. The front of the left frame (8) has a front collet assembled to side cover locking mechanisms as shown in FIG. 4.

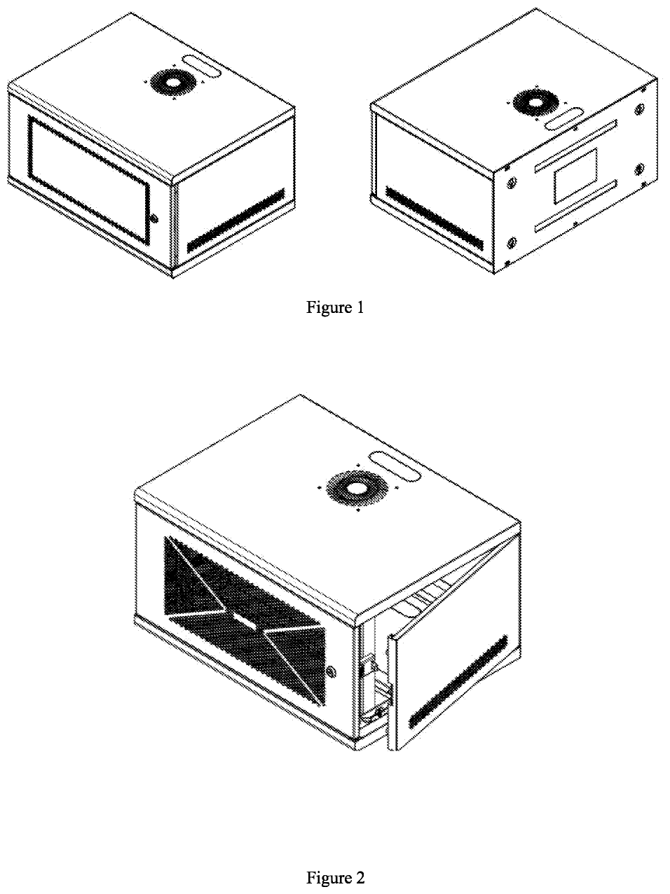

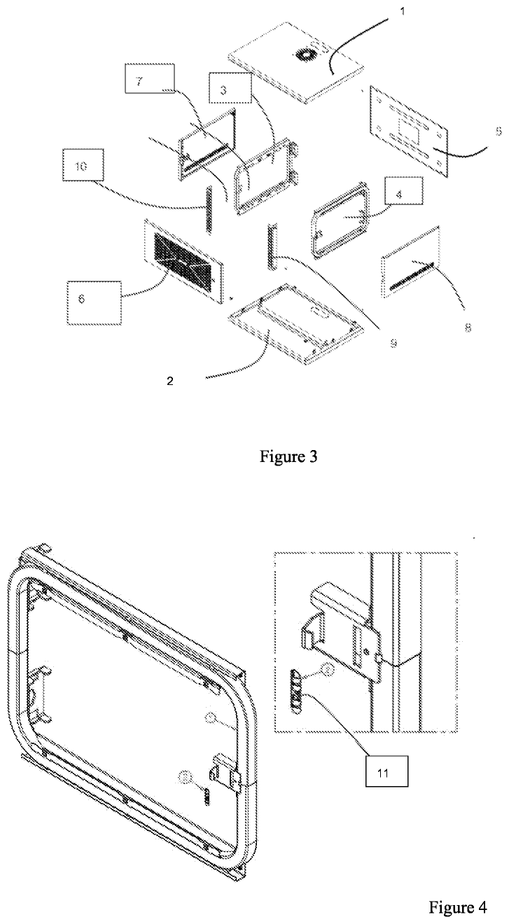

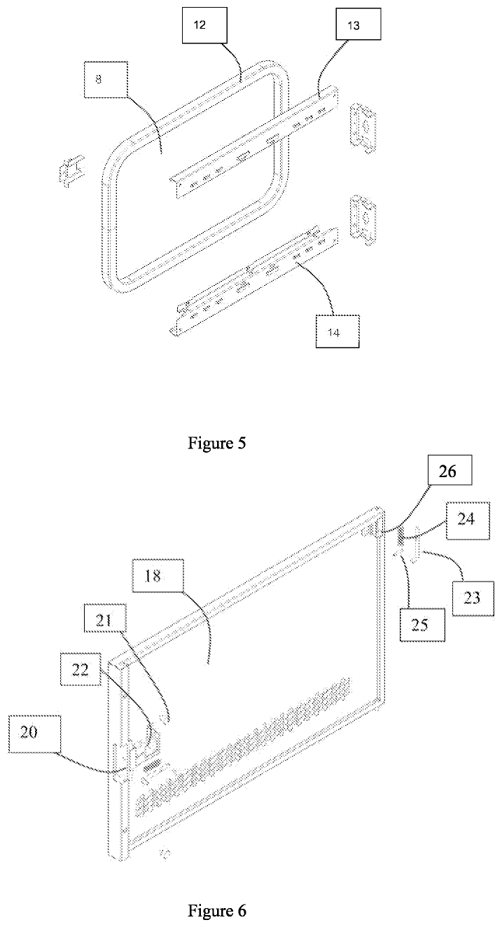

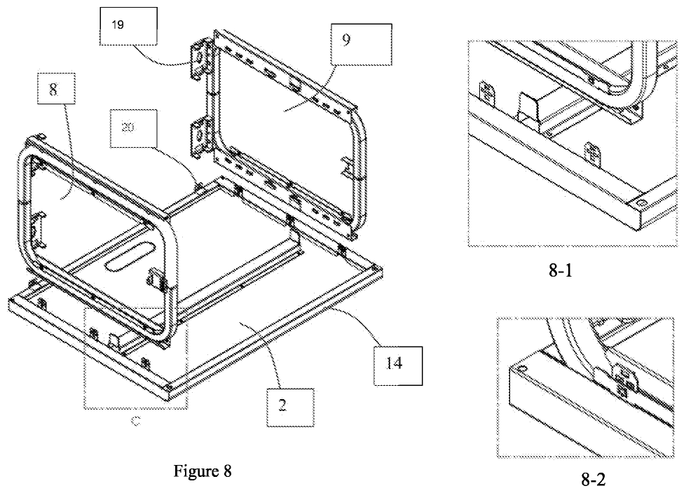

4. The mechanism for assembling the top cover (1) and the bottom cover (2) to the right frame (7) and the left frame (8) with wedges in FIG. 8-1 and FIG. 8-2 uses force to make the designed wedges lock into the aforementioned positions in order to assemble the structure together without need for screws.
